(19) United States
(12) Patent Application Publication
(10) Pub. No.: US 2010/0038774 A1
(43) Pub. Date: Feb. 18, 2010

(54) ADVANCED AND INTEGRATED COOLING FOR PRESS-PACKAGES

(75) Inventors: Richard S. Zhang, Rexford, NY (US); Richard Alfred Beaupre, Pittsfield, MA (US); Ramakrishna Venkata Mallina, Clifton Park, NY (US); Arun Virupaksha Gowda, Rexford, NY (US); Le Yan, Schenectady, NY (US); Ljubisa Dragoljub Stevanovic, Clifton Park, NY (US); Peter Morley, Fort Hunter, NY (US); Stephen Adam Solovitz, Portland, OR (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 12/193,429

(22) Filed: Aug. 18, 2008

(51) Int. Cl. H01L 23/34

(52) U.S. Cl. 257/714; 257/E23.08

(57) ABSTRACT

A heat sink for cooling at least one electronic device package is provided. The electronic device package has an upper contact surface and a lower contact surface. The heat sink comprises at least one thermally conductive material and defines multiple inlet manifolds configured to receive a coolant, multiple outlet manifolds configured to exhaust the coolant, and multiple millichannels configured to receive the coolant from the inlet manifolds and to deliver the coolant to the outlet manifolds. The manifolds and millichannels are disposed proximate to the respective one of the upper and lower contact surface of the electronic device package for cooling the respective surface with the coolant.

### BACKGROUND

The invention relates generally to power electronics and, more particularly, to advanced cooling for power electronics.

High power converters, such as medium voltage industrial drives, frequency converters for oil and gas, traction drives, Flexible AC Transmission (FACT) devices, and other high power conversion equipment, for example rectifiers and inverters, typically include press-pack power devices with liquid cooling. Non-limiting examples of power devices include integrated gate commutated thyristors (IGCTs), diodes, insulated gate bipolar transistors (IGBTs), thyristors and gate turn-off thyristors (GTOs). Press-pack devices are particularly advantageous in high power applications, and benefits of press-packs include double-sided cooling, as well as the absence of a plasma explosion event during failure.

To construct a high power converter circuit using press-pack devices, heat sinks and press-pack devices are typically sandwiched to form a stack. State-of-the-art power converter stacks typically employ conventional liquid cooled heat sinks with larger diameter cooling channels. The heat sinks and power devices are not integrated in state of the art power converter stacks. In certain applications, thermal grease layers are disposed between respective ones of the press-pack device and the liquid cooled heat sink. In other applications, at least some of the layers are simply held together by pressure, with no thermal grease in between them. This arrangement results in significant contact resistance. Other shortcomings of such power converter stacks include relatively high thermal impedance from the semiconductor junction to the liquid, as well as a relatively complex stack assembly structure and process due to the number of parts involved.

Accordingly, it would be desirable to improve the thermal performance and packaging of power converter stacks using press-pack devices. More particularly, it would be desirable to reduce the thermal impedance from the semiconductor junction to the liquid for high reliability and/or high power density.

### BRIEF DESCRIPTION

Briefly, one aspect of the present invention resides in a heat sink for cooling at least one electronic device package. The electronic device package has an upper contact surface and a lower contact surface. The heat sink comprises at least one thermally conductive material and defines multiple inlet manifolds configured to receive a coolant, multiple outlet manifolds configured to exhaust the coolant, and multiple millichannels configured to receive the coolant from the inlet manifolds and to deliver the coolant to the outlet manifolds. The manifolds and millichannels are disposed proximate to the respective one of the upper and lower contact surface of the electronic device package for cooling the respective surface with the coolant.

Another aspect of the present invention resides in a cooling and packaging stack comprising at least one heat sink defining multiple inlet manifolds configured to receive a coolant and multiple outlet manifolds configured to exhaust the coolant. The stack further comprises at least one electronic device package comprising an upper contact surface and a lower contact surface. At least one of the upper and lower contact surfaces defines multiple millichannels configured to receive the coolant from the inlet manifolds and to deliver the coolant to the outlet manifolds. The manifolds and millichannels are configured to directly cool the respective one of the upper and lower surfaces by direct contact with the coolant.

### DRAWINGS

These and other features, aspects, and advantages of the present invention will become better understood when the following detailed description is read with reference to the accompanying drawings in which like characters represent like parts throughout the drawings, wherein:

FIG. 1 depicts an electronic device package with upper and lower heatsinks;

FIG. 2 illustrates a circular manifold embodiment of the invention;

FIG. 3. is a cross-sectional view of the manifold arrangement of FIG. 2 taken along the line B-B;

FIG. 4. is another cross-sectional view of the manifold arrangement of FIG. 2 taken along the line A-A.;

FIG. 5 is an enlarged view of the region C in FIG. 2;

FIG. 6 illustrates a radial millichannel embodiment of the invention;

FIG. 7 is a cross-sectional view of the millichannel arrangement of FIG. 6 taken along the line A-A;

FIG. 8 illustrates a double-sided heatsink for cooling multiple electronic device packages;

FIG. 9 illustrates a cooling and packaging stack embodiment of the invention with double sided cooling;

FIG. 10 illustrates a cooling and packaging stack configured for a number of electronic device packages;

FIG. 11 depicts an exemplary manifold arrangement for a cooling and packaging stack configured for a number of electronic device packages;

FIG. 12 depicts another exemplary manifold arrangement for a cooling and packaging stack configured for a number of electronic device packages;

FIG. 13 illustrates an integrated cooling stack embodiment of the invention;

FIG. 14 illustrates a heatsink with millichannels and manifolds incorporated into a single cooling piece;

FIG. 15 shows the cross-section of a radial channel at the intersection with a circular channel for the heat sink of FIGS. 14 or 16;

FIG. 16 illustrates a heatsink design, which increases the number of radial channels;

FIG. 17 illustrates an exemplary metal foil bond; and

FIG. 18 illustrates an exemplary solder bond.

While the above-identified drawing figures set forth alternative embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION

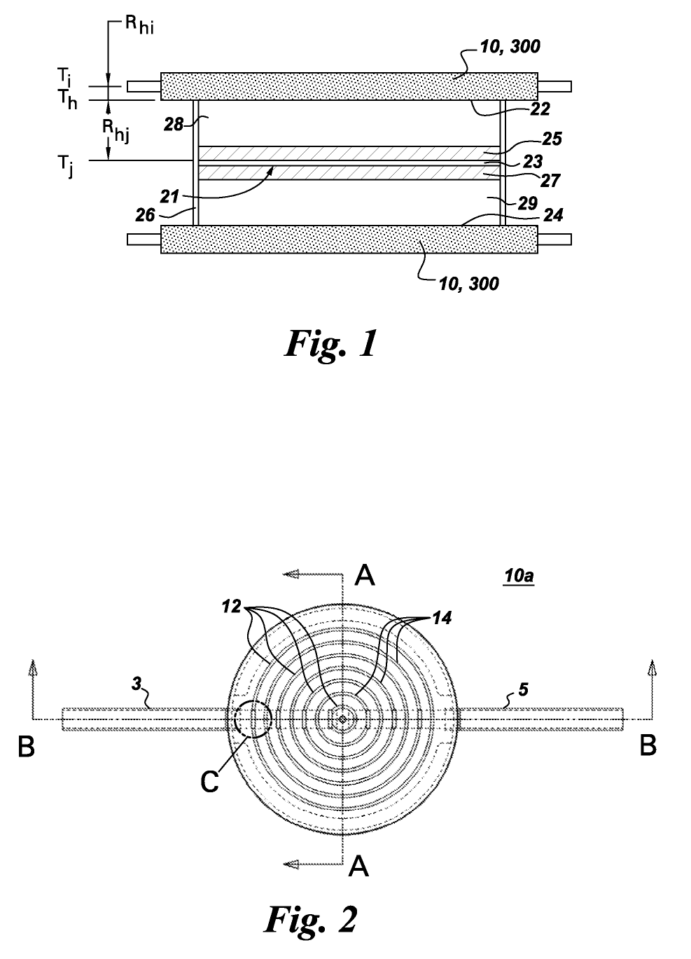

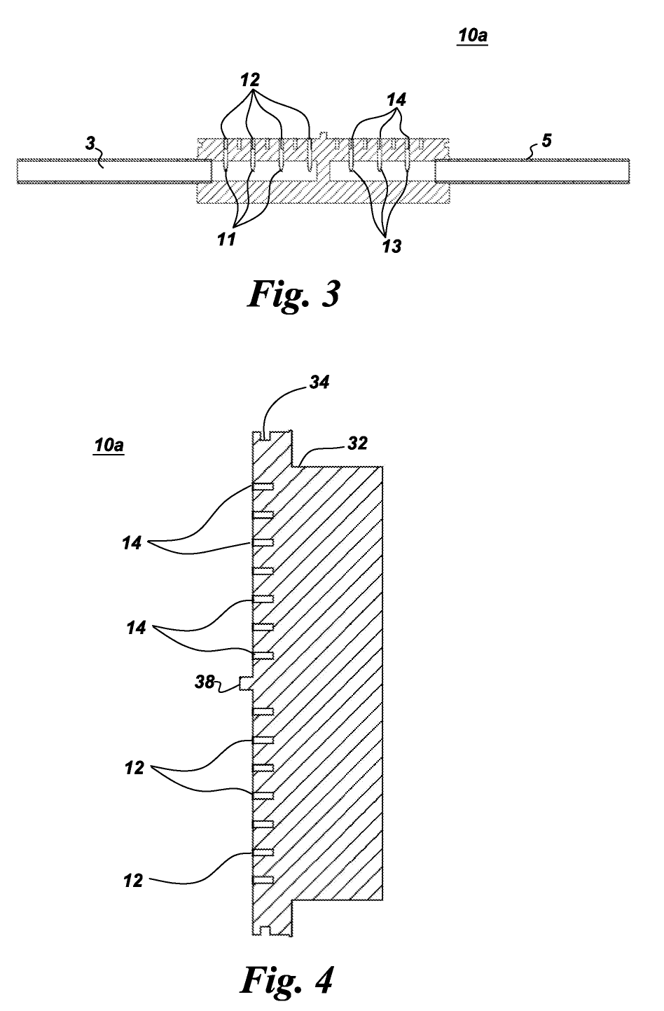

A heat sink 10 for cooling at least one electronic device package 20 is described with reference to FIGS. 1-8. As indicated for example in FIG. 1, an exemplary electronic device package 20 has an upper contact surface 22 and a lower contact surface 24. The heat sink 10 includes at least one thermally conductive material, and as shown for example in FIGS. 2-5 the heat sink defines a number of inlet manifolds 12 configured to receive a coolant and a number of outlet manifolds 14 configured to exhaust the coolant. As shown for example in FIGS. 2 and 3, the inlet and outlet manifolds are interleaved (interdigitated). Non-limiting examples of the thermally conductive material include copper, nickel, molybdenum, titanium, alloys, metal matrix composites such as aluminum silicon carbide (AlSiC) and ceramics such as silicon nitride ceramic. Non-limiting examples of the coolant include de-ionized water and other non-electrically conductive liquids. As shown for example in FIGS. 6 and 7, the heat sink 10 further includes a number of millichannels 16 configured to receive the coolant from the inlet manifolds 12 and to deliver the coolant to the outlet manifolds 14. According to more particular embodiments, the millichannels 16 and inlet and outlet manifolds 12, 14 are configured to deliver the coolant uniformly to the respective one of the upper and lower contact surface 22, 24 of the electronic device package being cooled. The manifolds 12, 14 and millichannels 16 are disposed proximate to the respective one of the upper and lower contact surface 22, 24 of the electronic device package 20 for cooling the respective surface with the coolant.

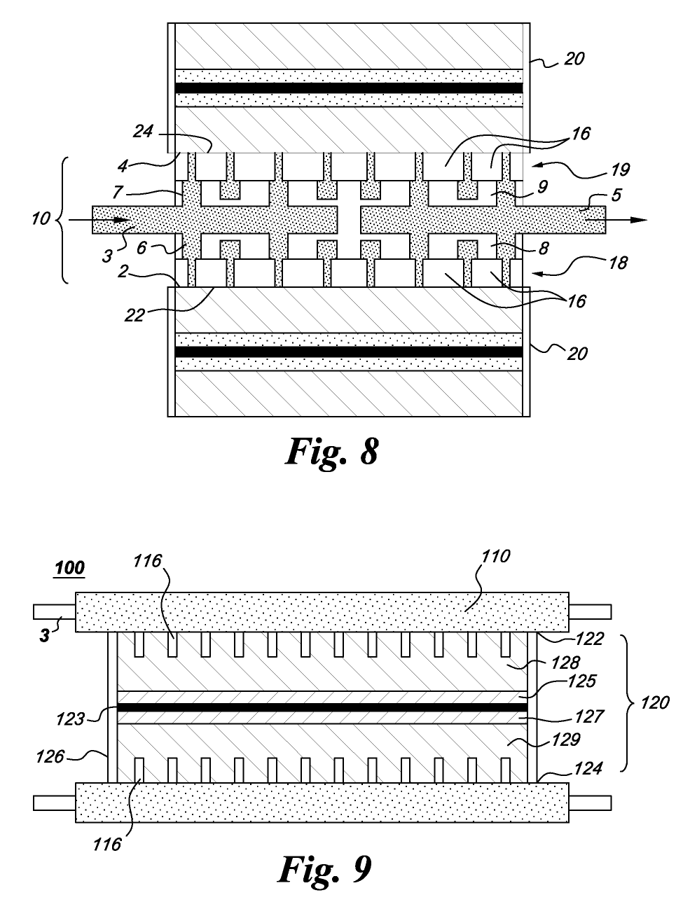

For the illustrated embodiment shown in FIGS. 2-7, the millichannels 16 are contained within the heat sink 10. With this arrangement, the heat sink 10 is connected to the face of the device package 20 to cool the device. This interface between the heat sink 10 and device package 20 can be dry (i.e., no interface material), thermal grease, metal foil or other thermal interface material. In other example arrangements, for example as shown in FIGS. 8-10 and 13, the millichannels 16 and inlet and outlet manifolds 12, 14 are configured to directly cool one of the upper and lower contact surface 22, 24 of the electronic device package 20 by direct contact with the coolant, such that the heat sink comprises an integral heat sink. These integral heat sink embodiments are particularly beneficial relative to conventional heat sinks. Conventional heat sinks are not integral to the press-packages but rather are self-contained, in that the coolant does not contact the power devices but rather is encased within the heat sink. Thus, conventional heat-sinks require additional thermal layers (the case), which impede heat transfer. In contrast, heat sinks, which are disposed integral to the press-packages, directly cool the power devices with direct contact by the coolant, thereby enhancing the heat transfer.

For particular embodiments, the manifolds 12, 14 have relatively larger diameters than the millichannels 16. In one non-limiting example, the width of the millichannels is in a range of about 0.5 mm to about 2.0 mm, and the depth of the millichannels is in a range of about 0.5 mm to about 2 mm. In particular, the thickness of the channels may be determined to ensure pressure uniformity on the semiconductor. By making the pressure distribution on the semiconductor more uniform, the performance of the semiconductor is not compromised. Further, it should be noted that the millichannels 16 and manifolds 12, 14 could have a variety of cross-sectional shapes, including but not limited to, rounded, circular, triangular, trapezoidal, and square/rectangular cross sections. The channel shape is selected based on the application and manufacturing constraints and affects the applicable manufacturing methods, as well as coolant flow. Beneficially, the incorporation of millichannels 16 into the heat sink 10 significantly increases the surface area of heat conduction from the semiconductor device 20 to the coolant.

In one example (not illustrated), the inlet and outlet manifolds 12, 14 are disposed in a radial arrangement, and the millichannels 16 are disposed in a circular (also referred to herein as axial) arrangement. As used herein, the phrases “circular arrangement” and “axial arrangement” should be understood to encompass both curved and straight millichannels connecting the radial manifolds.

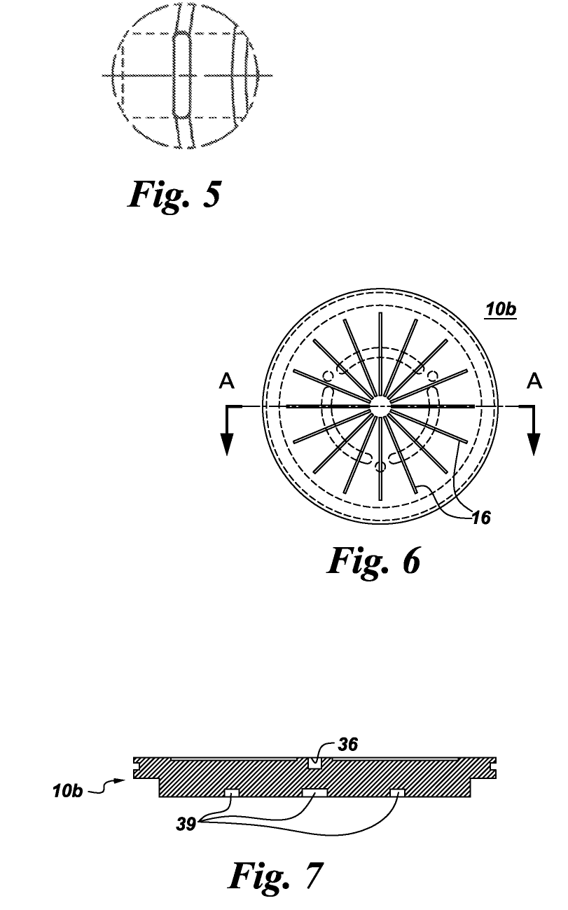

FIGS. 2-5 show an exemplary manifold piece 10a having inlet and outlet manifolds 12, 14 disposed in a circular arrangement. The example arrangement shown in FIGS. 2-7 is self-contained, in that interface material is provided between the heat sink 10 and the electronic device package 20. As indicated in FIG. 3, for example, the coolant is supplied to heat sink 10 via an inlet plenum 3. The coolant then flows into the inlet manifolds (alternate concentric manifold sections) 12 via inlet ports 11, as indicated for example in FIG. 3. After passing through the millichannels, the coolant is exhausted from the outlet manifolds 14 (the other alternate concentric manifold sections) via outlet ports 13 to the outlet plenum 5, as indicated in FIG. 3, for example. The inlet and outlet manifolds 12, 14 are indicated in FIG. 4, which shows a cross-section of the manifold piece 10a taken along the line A-A. It should be noted that the cutback 32 and notch 34 are specific to the illustrated example. For the illustrated example the notch 34 is configured to accommodate an O-ring (not shown). FIG. 5 is an enlarged view of an exemplary inlet port 11.

For the exemplary arrangement shown in FIG. 6, the millichannels 16 are disposed in a radial arrangement. FIG. 6 is a top view of a radial arrangement of millichannels 16 formed in millichannel piece 10b. A cross-sectional view of the millichannel piece 10b taken along the line A-A is shown in FIG. 7. For the illustrated example, millichannel piece 10b defines a hole 36 for receiving an alignment pin 38 of the manifold piece 10a. In another example (not shown), the manifold piece 10a defines a hole (not shown) for receiving an alignment pin (not shown) mounted on the millichannel piece 10b. In the illustrated example, the millichannel piece 10b further defines a number of grooves 39. The grooves 39 in this example were placed for structural reasons to match a test fixture and the press-pack internal design. The millichannel piece 10b can be formed using a variety of thermally conductive materials, non-limiting examples of which include copper, aluminum, nickel, molybdenum, titanium, alloys thereof, metal matrix composites such as aluminum silicon carbide (AlSiC), aluminum graphite and ceramics, such as silicon nitride ceramic. In particular embodiments, multiple materials are used to form the millichannel piece. For example, ALSiC and aluminum are used, with aluminum being used in the millichannel region for ease of machining. The millichannel piece can be cast and/or machined. For example, the millichannel piece 10b can be cast and then machined to further define fine features and surface requirements.

To form the heatsink 10, the manifold piece 10a and millichannel piece 10b are mated such that the coolant flows to alternate concentric manifold sections (inlet manifolds) 12, then through the radial millichannels 16, and is exhausted via the other alternate concentric manifold sections (outlet manifolds) 14. In particular, the manifold piece 10a and millichannel piece 10b should be bonded to one another such that no leakage of the coolant occurs. More particularly, the bond should be mechanically robust. For example, the material used to form the bond between the manifold piece 10a and millichannel piece 10b should be selected to ensure that the mechanical reliability of the heatsink is robust. Non-limiting means for bonding the manifold piece 10a and millichannel piece 10b to one another include solder bonds and metal foil bonds. FIG. 18 illustrates an exemplary solder bond, in which solder is first deposited on at least a portion of the surface of the millichannel piece 10b, other than over the millichannels, which are kept free of the solder. The type of solder can vary However, non-limiting examples of suitable solders include Sn-based solders (such Sn—Pb, Sn—Pb—Ag, Sn—Ag, Sn—Ag—Cu, Sn—Ag—Bi, Sn—Ag—Sn, etc.), high lead containing solders (Pb—Sn, Pb—Sn—Ag, Pb—In—Ag), and Au-based solders (Au—Sn, Au—Ge, Au—Si, Au—In). Brazing materials based on Ag and Zn can also be used to form the manifold piece. Glass frit materials and structural polymeric materials (silicones, epoxies) can be used to form the manifold for specific applications.

For certain embodiments, the joining process for forming the manifold comprises: first apply the joining material in form of a foil or paste at the desired locations on one side of the manifold piece, followed by alignment and placement of the second piece, and joining the two parts to obtain the manifold assembly. Foils can be aligned and placed using a placement machine. FIG. 18 illustrates an exemplary metal foil bond. As indicated grooves 322 are formed through metal foil 320. The grooves 322 are aligned with the millichannels 16, and the metal foil is used to bond the manifold piece 10a and millichannel piece 10b to one another. The type of metal foil can vary based on the materials used to form manifold piece 10a and millichannel piece 10b. However, non-limiting examples of suitable metal foils include an Indium foil.

Paste type joining materials can be dispensed or printed using a stencil. The final joining process typically involves the application of a specific pressure on the assembly and a thermal excursion through the melting/curing/reflow temperature of joining material. A key characteristic of the joining material and process should be that the material does not flow into the channels such that the channel dimensions are significantly altered. Specifically for solders, certain metallization schemes are preferred to allow adequate wetting of the molten solder to the manifold surfaces. These metal finishes can be applied only at desired locations, outside the channels, using masking techniques or by cutting channels in the base metal after metalizing the surfaces. This ensures that the channels do not have a metal finish that is wettable by the solder. Another approach is to use control the solder height through shims and controlled solder volumes such that only negligible amounts of solder flow into the channels and the change in channel dimensions are negligible. An alternative approach is to fill channels with a material that will occupy the channels during the attachment process and then removed using solvents, thus achieving channels that are free from the joining material.

Other heat sink arrangements employing a single piece for both manifolds and millichannels are discussed with reference to FIGS. 14-16. FIG. 14 illustrates a heatsink 300 with millichannels 16 and manifolds 12, 14 incorporated into a single cooling piece 310. In the illustrated example, cooling piece 310 defines a groove 302 for receiving an O-ring (not shown). As with the example arrangement discussed above with reference to FIGS. 2-7, the inlet and outlet manifolds 12, 14 may be disposed in a circular (axial) arrangement, with radially arranged millichannels 16 configured to receive coolant from the inlet manifolds 12 and convey the coolant to the outlet manifolds 14. Alternatively, the millichannels may be arranged in a circular (axial) pattern, with radial inlet and outlet manifolds. The cooling piece 310 can be formed using a variety of thermally conductive materials, non-limiting examples of which are discussed above with reference to millichannel piece 10b. In particular embodiments, multiple materials are used to form the millichannel piece. For example, ALSiC and aluminum are used, with aluminum being used in the millichannel region for ease of machining. The millichannel piece can be cast and/or machined. For example, the cooling piece 310 can be cast and then machined to further define fine features.

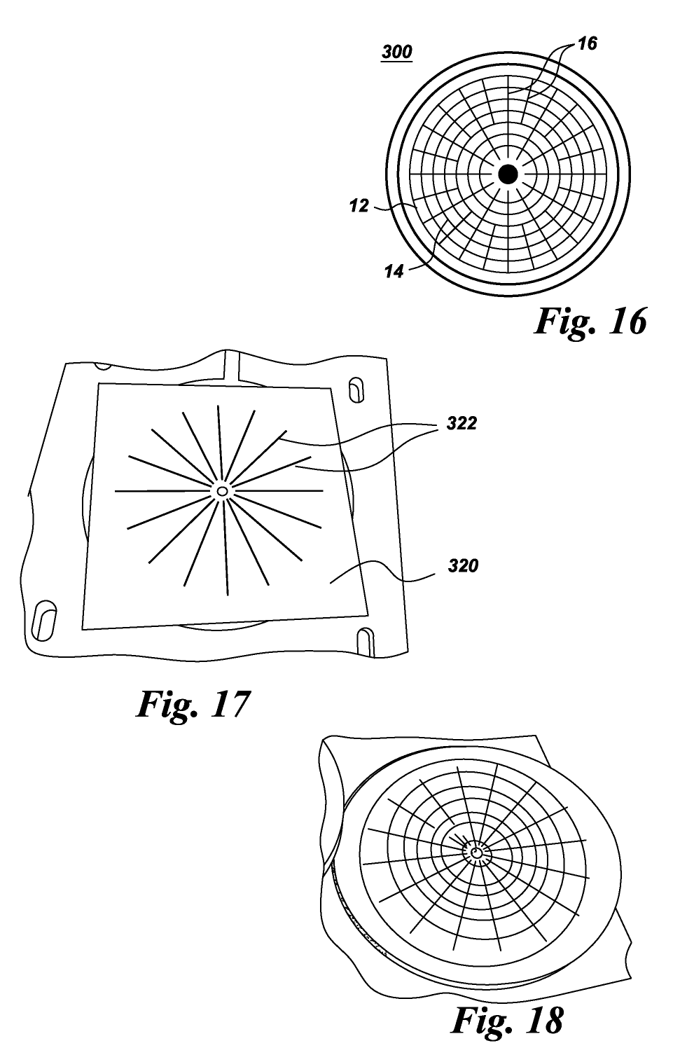

FIG. 15 shows the cross-section of a radial channel at the intersection with a circular channel. FIG. 16 illustrates a design to increase the number of radial channels to facilitate a reduction in pressure drop with a corresponding improvement in cooling efficiency. As noted above, although the radial channels are designated as millichannels by reference numeral 16, the radial channels could also serve as manifolds 12, 14 in cooperation with circularly arranged millichannels.

Beneficially, by incorporating the millichannels and inlet/outlet manifolds into a single piece as illustrated in FIGS. 14-16, for example, the assembly process is simplified. In particular, the use of a single cooling piece 310 eliminates the need to bond two components. Instead, heat sink 300 can be assembled using an O-ring assembly.

FIG. 8 illustrates an exemplary heat sink 10 embodiment for cooling a number of electronic device packages 20. As indicated in FIG. 8, the millichannels 16 are arranged in a first set 18 and a second set 19. The first set 18 of millichannels is arranged at a first surface 2 of the heat sink 10, and the second set 19 of millichannels is arranged at a second surface 4 of the heat sink 10. For the illustrated embodiment, the first set 18 of millichannels is configured to directly cool an upper contact surface 22 of one of the electronic device packages 20 by direct contact with the coolant, and the second set 19 of millichannels is configured to directly cool a lower contact surface 24 of another of the electronic device packages 20 by direct contact with the coolant. According to a more particular embodiment, the inlet manifolds 12 are arranged in a first set 6 and a second set 7, and the outlet manifolds 14 are arranged in a first set 8 and a second set 9. The first sets of inlet and outlet manifolds 6, 8 are configured to supply and exhaust the coolant from the first set 18 of millichannels, and the second sets of inlet and outlet manifolds 7, 9 are configured to supply and exhaust the coolant from the second set 19 of millichannels.

For the exemplary embodiments described above with reference to FIGS. 1-8, the upper contact surface 22 and lower contact surface 24 can be circular in cross-section, and the heat sink 10 can be cylindrical (i.e., a disk or hockey-puck arrangement). However, other geometries can be employed, including without limitation, square and rectangular cross-sections. For the example arrangement depicted in FIG. 1, the electronic device package 20 is a press-package 20. Although the invention is not limited to any specific device structure, the following example press-package configuration is provided for illustrative purposes. In the example, the press-package 20 comprises at least one semiconductor device 21 formed on a wafer 23, upper and lower thermal-expansion coefficient (CTE) matched plates 25, 27, and upper and lower electrodes 28, 29. The wafer 23 is disposed between the CTE plates 25, 27, the upper electrode 28 is disposed above the upper CTE plate 25, and the lower CTE plate 27 is disposed above the lower electrode 19, as shown for example in FIG. 1. For the press-package embodiment, each of the wafer 23, CTE plates 25, 27 and electrodes 28, 29 has a circular cross-section. Non-limiting examples of semiconductor devices include IGCTs, GTOs and IGBTs. The present invention finds application to semiconductor devices manufactured from a variety of semiconductors, non-limiting examples of which include silicon (Si), silicon carbide (SiC), gallium nitride (GaN), and gallium arsenide (GaAs). The press-package typically includes an insulating (for example, ceramic) housing 26, as indicated for example in FIG. 1. Although FIG. 1 shows the heat sinks as extending outside the housing 26, in other embodiments, the heat sinks are disposed within the housing 26. Moreover, electrodes 28, 29 can extend vertically beyond the bounds of housing 26, for example with a compliant seal disposed between the outer circumference of electrodes 28 (and 29) and the housing 26. In addition, the heat sinks can extend out of the housing (as shown) to enable electrical connections and for placing other devices that need to be cooled. Therefore, the central portions of the heat sinks can have a larger diameter than housing 26

Similarly, the heat sinks 300 discussed above with reference to FIGS. 14-16 can have circular cross-sections and can be cylindrical (i.e., a disk or hockey-puck arrangement). Accordingly, heat sinks 300 can be used to cool the press-pack electronic device package 20 discussed above with reference to FIG. 1.

Beneficially, heat sinks 10 provide enhanced heat transfer relative to conventional cooling of power devices. The interleaved inlet and outlet channels deliver coolant uniformly to the surface of the device being cooled, and the millichannels increase the surface area of heat conduction from the power device to the coolant in this integral heat sink. For the embodiments illustrated in FIGS. 1-8, the heat sinks 10 are adapted for use with existing electronic packages 20, such as press-packages 20. Accordingly, heat sinks 10 can be used to cool conventional press-pack power devices without modification of the device packages.

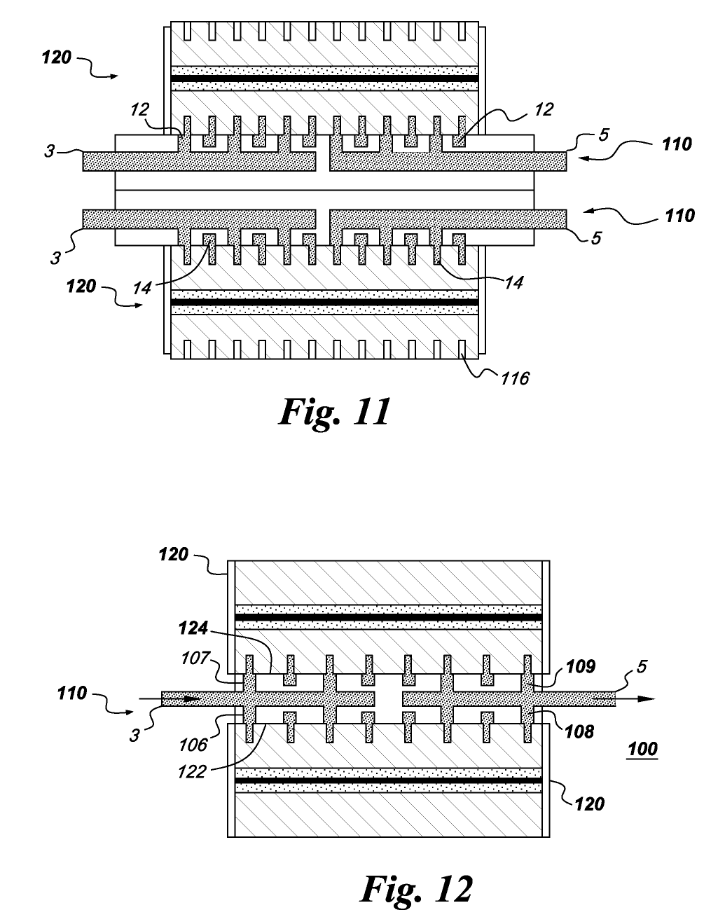

A cooling and packaging stack 100 embodiment of the invention is described with reference to FIGS. 9-12. The manifold arrangement for the cooling and packaging stack 100 is the same as discussed above for the heat sink 10, and the same reference numbers are used for the manifolds. Cooling and packaging stack 100 includes at least one heat sink 110 defining a number of inlet manifolds 12 configured to receive a coolant and a number of outlet manifolds 14 configured to exhaust the coolant. (See, for example, FIG. 11.) Exemplary materials for heat sink 110 are discussed above with reference to heat sink 10. Inlet and outlet manifolds 12, 14 are described above with reference to FIGS. 2-5. FIG. 9 illustrates a double-sided cooling configuration with two heat sinks 110. For the illustrated embodiment, coolant is supplied through inlet plenum 3 and exhausted via outlet plenum 5.

As indicated in FIG. 9, cooling and packaging stack 100 further includes at least one electronic device package 120 having an upper contact surface 122 and a lower contact surface 124, where at least one of the upper and lower contact surfaces defines a number of millichannels 116 configured to receive the coolant from the inlet manifolds 12 and to deliver the coolant to the outlet manifolds 14. For the exemplary embodiment illustrated in FIG. 9, millichannels 116 are formed in each of the upper and lower contact surfaces 122, 124. For the illustrated embodiment, the manifolds 12, 14 and millichannels 116 are configured to directly cool respective ones of the upper and lower contact surfaces 122, 124 by direct contact with the coolant. For particular embodiments, the manifolds 12, 14 have relatively larger diameters than the millichannels 116.

The relative arrangements of the manifolds and millichannels are similar to those described above with reference to FIGS. 2-7. In one embodiment, the inlet and outlet manifolds 12, 14 are disposed in a radial arrangement, and the millichannels 116 are disposed in a circular arrangement. In another embodiment, the millichannels 116 are disposed in a radial arrangement (as shown for millichannels 16 in FIGS. 6 and 7) and the inlet and outlet manifolds 12, 14 are disposed in a circular (or more generally, in an axial) arrangement, as shown in FIGS. 2-5. For the cooling and packaging stack 100, the heat sink(s) 110 is (are) mated to respective ones of the upper and lower contact surfaces 122, 124 of the electronic device package 120 such that the coolant flows from the inlet manifolds in the heat sink, through the millichannels in the upper and lower contact surfaces of the electronic device package 120, and out the outlet manifolds in the heat sink. In particular, the heat sinks 110 should be bonded to the respective ones of the upper and lower contact surfaces 122, 124 such that no leakage of the coolant occurs. In addition, the bond between the heat sinks and the device package should be mechanically robust.

For the exemplary embodiment illustrated in FIG. 9, the stack 100 includes a number of heat sinks 110 (in this case two heat sinks 110) with at least one of the heat sinks disposed above the upper contact surface 122 of one of the electronic device packages 120, and at least another of the heat sinks disposed below the lower contact surface 124 of the electronic device package 120. For the illustrated embodiment, each of the upper and lower contact surfaces 122, 124 of the electronic device package 120 defines a number of millichannels 116 configured to receive the coolant from the inlet manifolds 12 and to deliver the coolant to the outlet manifolds 14 formed in neighboring ones of the heat sinks. For the illustrated embodiment, the manifolds and millichannels are configured to directly cool the respective ones of the upper and lower contact surfaces 122, 124 by direct contact with the coolant.

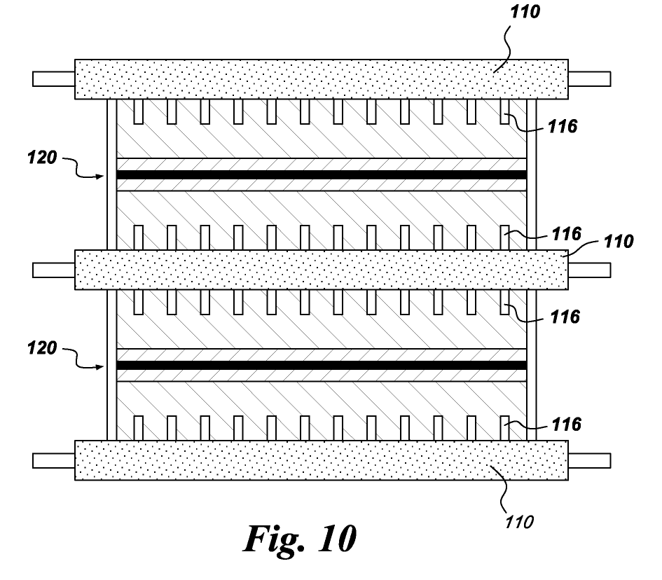

FIGS. 10 and 11 depict other embodiments of cooling and packaging stack 100 that include a number of electronic device packages 120. As indicated in FIGS. 10 and 11, the heat sinks 110 and electronic device packages are alternately arranged. For the illustrated arrangement of FIG. 10, single heat sinks 110 are disposed between neighboring electronic packages 120, such that inlet and outlet manifolds 12, 14 are provided in the heat sinks 110 to respectively deliver and exhaust coolant from the millichannels in the electronic device packages 120 immediately above and below a respective heatsink 110. One exemplary manifold arrangement for the embodiment of FIG. 10 would be similar to that shown in FIG. 8. FIG. 11 depicts another configuration with two heat sinks 110 disposed between neighboring electronic packages 120, such that the inlet and outlet manifolds 12, 14 in a given heat sink 110 respectively deliver and exhaust coolant from the millichannels in a single adjacent electronic device package 120.

FIG. 12 illustrates a particular embodiment of cooling and packaging stack 100 that includes a number of electronic device packages 120. For each of the heat sinks 110, the inlet manifolds 12 are arranged in a first set 106 and a second set 107, and the outlet manifolds 14 are arranged in a first set 108 and a second set 109, as indicated in FIG. 12. The first set of inlet and outlet manifolds 106, 108 are arranged at a first surface 102 of the heat sink 110, and the second sets of inlet and outlet manifolds 107, 109 are arranged at a second surface 104 of the heat sink 110. The first sets of inlet and outlet manifolds 106, 108 are configured to supply and exhaust the coolant to the millichannels 116 formed in the upper contact surface 122 of one of the electronic device packages 120, and the second sets of inlet and outlet manifolds 107, 109 are configured to supply and exhaust coolant to the millichannels 116 formed in the lower contact surface 124 of another of the electronic device packages 120. As shown for example in FIG. 12, the heat sink 110 can be formed of a single piece with manifolds formed on both surfaces. Similarly, as shown for example in FIG. 11, the heat sink 110 can be formed of two pieces, with manifolds formed on the outer surface of each piece and the inner surfaces adjoining one another.

For the exemplary embodiments discussed above with reference to FIGS. 9-12, each of the upper contact surface 122 and lower contact surface 124 can be circular in cross-section, and each of the heat sinks 110 can be cylindrical in cross-section (i.e., a disk or hockey-puck arrangement). According to more particular embodiments, the electronic device package 120 is a press-package 120. As noted above, the invention is not limited to any specific device structure. However, the following example press-package configuration is provided for illustrative purposes. In the example, the press-package 120 comprises at least one semiconductor device 121 formed on a wafer 123, as shown for example in FIG. 9. The press package 120 further includes an upper and a lower thermal-expansion coefficient (CTE) matched plates 125, 127 and an upper and a lower electrode 128, 129, as indicated in FIG. 9. The wafer 123 is disposed between the CTE plates 125, 127. The upper electrode 128 is disposed above the upper CTE plate 125, and the lower CTE plate 127 is disposed above the lower electrode 129. Each of the wafer 123, CTE plates 125, 127 and electrodes 128, 129 has a circular cross-section. Example semiconductor devices are discussed above.

Beneficially, cooling and packaging stack 100 provides enhanced heat transfer relative to conventional cooling of power devices. For example, cooling and packaging stack 100 directly cools the device press-package by contact with the coolant, thereby reducing the thermal resistance and enhancing reliability. In addition, by locating narrow and deep millichannels 116 directly under the power devices, the heat transfer surface area from the junction of the device to the liquid is maximized. Relative to a conventional stack assembly of press-pack devices and liquid cooled heat sinks, the thermal resistance is greatly reduced with relatively low pressure drop and flow rate.

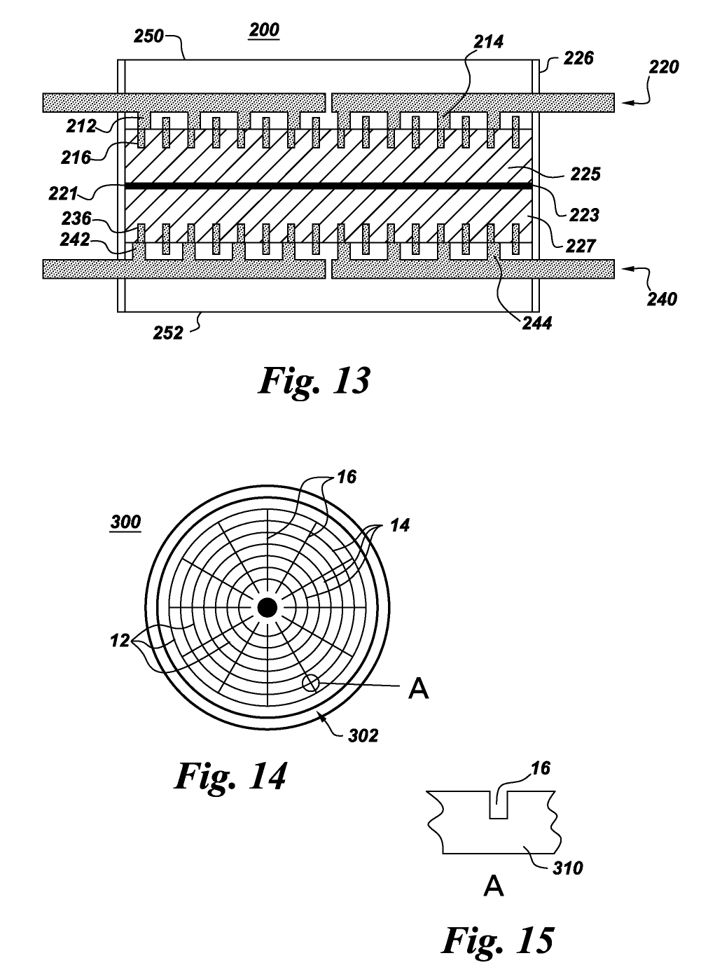

An integrated cooling stack 200 embodiment of the invention is described with reference to FIG. 13. As shown for example in FIG. 13, the integrated cooling stack 200 includes an upper heat sink 220 defining a number of upper inlet manifolds 212 for supplying a coolant and a number of upper outlet manifolds 214 for exhausting the coolant. The integrated cooling stack 200 further includes a lower heat sink 240 defining a number of lower inlet manifolds 242 for supplying a coolant and a number of lower outlet manifolds 244 for exhausting the coolant. The integrated cooling stack 200 further includes an upper thermal-expansion coefficient (CTE) matched plate 225 defining a number of upper millichannels 216 configured to receive the coolant from the upper inlet manifolds 212 and to exhaust the coolant to the upper outlet manifolds 214. The integrated cooling stack 200 further includes a lower CTE matched plate 227 defining a number of lower millichannels 236 configured to receive the coolant from the lower inlet manifolds 242 and to exhaust the coolant to the lower outlet manifolds 244. For particular embodiments, the manifolds 212, 214, 242, 244 have relatively larger diameters than the millichannels 216, 236.

For the particular embodiment shown in FIG. 13, the integrated cooling stack 200 further includes an insulating housing 226. As indicated, the upper and lower heat sinks 220, 240 and the upper and lower CTE matched plates 225, 227 are disposed in the housing 226. For the illustrated embodiment, the housing 226 extends around the perimeters of the heat sinks 220, 240 and CTE matched plates 225, 227, while an upper side 250 of the upper heat sink 220 and a lower side 252 of the lower heat sink 240 remain exposed for contact to other modules and or circuit or machine elements (not shown).

The relative arrangements of the manifolds and millichannels are similar to those described above with reference to FIGS. 2-7. In one embodiment, at least one of the upper inlet and outlet manifolds 212, 214 and the lower inlet and outlet manifolds 242, 244 are disposed in radial arrangements, and at least one of the upper and lower millichannels (216, 236) are disposed in circular (axial) arrangements. In one example, all of the inlet and outlet manifolds 212, 242, 214, 244 are disposed in radial arrangements and all of the millichannels 216, 236 are disposed in circular (axial) arrangements. In another example, the arrangements of the manifolds and millichannels differ for the upper and lower heat sinks 220, 240 and for the upper and lower CTE matched plates 225, 227. For example, the millichannels 216 might be radially arranged (and the manifolds 212, 214 circularly arranged) for the upper CTE matched plate 225 and heat sink 220, whereas for the lower CTE matched plate 227 and hear sink 240, the millichannels 236 might be circularly (axially) arranged (and the manifolds 242, 244 radially arranged), or vice versa.

For other embodiments similar to those discussed above with reference to FIGS. 2-7, at least one of the upper and lower millichannels 216, 236 are disposed in a radial arrangement, and at least one of the upper and lower inlet and outlet manifolds 212, 242, 214, 244 are disposed in a circular (axial) arrangement. As noted above, for certain applications, the millichannel/manifold arrangements for the upper and lower cooling portions may be the same, whereas for other applications, the millichannel/manifold arrangements may differ for the upper and lower cooling portions.

For the illustrated embodiment, each of the upper and lower (CTE) matched plates 225, 227 can be circular in cross-section, and each of the upper and lower heat sinks 220, 240 can be circular in cross-section. The invention is not limited to any specific device structure. However, the following example press-package configuration is provided for illustrative purposes. In the example, the integrated cooling stack 200 further includes a housing 226 and at least one semiconductor device 221 formed on a wafer 223, where the wafer is disposed between the upper and lower CTE plates 225, 227. In a particular, non-liming example, each of the wafer 223, upper and lower CTE plates 225, 227, and upper and lower heat sinks 220, 240 has a circular cross-section and is arranged in the housing 226 to form a press-package 200.

Beneficially, integrated cooling stack 200 provides enhanced heat transfer and reliability relative to conventional cooling of power devices. For example, heat transfer is enhanced by forming the millichannels 216, 236 in the CTE matched plates 225, 227, such that coolant is supplied directly to the CTE matched plates. Other benefits of integrated cooling stack 200 include its compactness, simple stack assembly, as well as potentially lower cost due to reduced cooling needs and simple stack assembly.

By providing higher reliability and a larger operating margin due to improved thermal performance, the heat sink 10, cooling and packaging stack 100 and integrated cooling stack 200 are particularly desirable for applications demanding very high reliability, such as oil and gas liquefied natural gas (LNG) and pipeline drives, oil and gas sub-sea transmission and drives. In addition, the heat sink 10, cooling and packaging stack 100 and integrated cooling stack 200 can be employed in a variety of applications, non-limiting examples of which include high power applications, such as metal rolling mills, paper mills and traction, etc.

Although only certain features of the invention have been illustrated and described herein, many modifications and changes will occur to those skilled in the art. It is, therefore, to be understood that the appended claims are intended to cover all such modifications and changes as fall within the true spirit of the invention.

1. A heat sink for cooling at least one electronic device package, the electronic device package having an upper contact surface and a lower contact surface, the heat sink comprising at least one thermally conductive material, the heat sink defining:
a plurality of inlet manifolds configured to receive a coolant;
a plurality of outlet manifolds configured to exhaust the coolant; and
a plurality of millichannels configured to receive the coolant from the inlet manifolds and to deliver the coolant to the outlet manifolds, wherein the manifolds and millichannels are disposed proximate to the respective one of the upper and lower contact surface of the electronic device package for cooling the respective surface with the coolant.

2. The heat sink of claim 1, wherein the inlet and outlet manifolds are disposed in a radial arrangement, and wherein the millichannels are disposed in a circular arrangement.

3. The heat sink of claim 1, wherein the millichannels are disposed in a radial arrangement, and wherein the inlet and outlet manifolds are disposed in a circular arrangement.

4. The heat sink of claim 1, wherein the at least one thermally conductive material is selected from the group consisting of copper, aluminum, nickel, molybdenum, titanium, copper alloys, nickel alloys, molybdenum alloys, titanium alloys, aluminum silicon carbide (AlSiC), aluminum graphite and silicon nitride ceramic.

5. The heat sink of claim 1 for cooling a plurality of electronic device packages, wherein the millichannels are arranged in a first set and a second set (19), wherein the first set of millichannels is arranged at a first surface of the heat sink, wherein the second set of millichannels is arranged at a second surface of the heat sink, wherein the first set of millichannels is configured to cool an upper contact surface of one of the electronic device packages with the coolant, and wherein the second set of millichannels is configured to cool a lower contact surface of another of the electronic device packages with the coolant.

6. The heat sink of claim 5, wherein the inlet manifolds are arranged in a first set and a second set, wherein the outlet manifolds are arranged in a first set and a second set, wherein the first sets of inlet and outlet manifolds are configured to supply and exhaust the coolant from the first set of millichannels, and wherein the second sets of inlet and outlet manifolds are configured to supply and exhaust the coolant from the second set of millichannels.

7. The heat sink of claim 1, wherein the upper contact surface and lower contact surface are circular in cross-section, and wherein the heat sink is cylindrical.

8. The heat sink of claim 1, wherein the millichannels and inlet and outlet manifolds are configured to directly cool one of the upper and lower contact surface of the electronic device package by direct contact with the coolant, such that the heat sink comprises an integral heat sink.

9. The heat sink of claim 1, further comprising a manifold piece defining the manifolds and a millichannel piece defining the millichannels.

10. The heat sink of claim 9, wherein the millichannel piece and manifold piece are bonded to one another via a solder bond or a metal foil bond.

11. The heat sink of claim 10, wherein the millichannels are disposed in a radial arrangement, and wherein the inlet and outlet manifolds are disposed in a circular arrangement, wherein the millichannel piece and manifold piece are bonded to one another via a metal foil bond comprising a metal foil defining a plurality of grooves, and wherein the grooves are aligned with the millichannels.

12. A cooling and packaging stack comprising:
at least one heat sink defining a plurality of inlet manifolds configured to receive a coolant and a plurality of outlet manifolds configured to exhaust the coolant;
at least one electronic device package comprising an upper contact surface and a lower contact surface, wherein at least one of the upper and lower contact surfaces defines a plurality of millichannels configured to receive the coolant from the inlet manifolds and to deliver the coolant to the outlet manifolds, wherein the manifolds and millichannels are configured to directly cool the respective one of the upper and lower surfaces by direct contact with the coolant.

13. The stack of claim 12, wherein the inlet and outlet manifolds are disposed in a radial arrangement, and wherein the millichannels are disposed in a circular arrangement.

14. The stack of claim 12, wherein the millichannels are disposed in a radial arrangement, and wherein the inlet and outlet manifolds are disposed in a circular arrangement.

15. The stack of claim 12, wherein the heat sink comprises at least one thermally conductive material selected from the group consisting of copper, aluminum, nickel, molybdenum, titanium, copper alloys, nickel alloys, molybdenum alloys, titanium alloys, aluminum silicon carbide (AlSiC), aluminum graphite and silicon nitride ceramic.

16. The stack of claim 12, comprising a plurality of heat sinks, wherein at least one of the heat sinks is disposed above the upper contact surface of one of the electronic device packages, wherein at least another of the heat sinks is disposed below the lower contact surface of the electronic device package, wherein each of the upper and lower contact surfaces of the electronic device package defines a plurality of millichannels configured to receive the coolant from the inlet manifolds and to deliver the coolant to the outlet manifolds formed in neighboring ones of the heat sinks, and wherein the manifolds and millichannels are configured to directly cool the respective ones of the upper and lower contact surfaces by direct contact with the coolant.

17. The stack of claim 16, comprising a plurality of electronic device packages, wherein the heat sinks and electronic device packages are alternately arranged.

18. The stack of claim 16, comprising a plurality of electronic device packages, wherein for each of the heat sinks, the inlet manifolds are arranged in a first set and a second set and the outlet manifolds are arranged in a first set and a second set, wherein the first set of inlet and outlet manifolds are arranged at a first surface of the heat sink, wherein the second sets of inlet and outlet manifolds are arranged at a second surface of the heat sink, wherein the first sets of inlet and outlet manifolds are configured to supply and exhaust the coolant to the millichannels formed in the upper contact surface of one of the electronic device packages, and wherein the second sets of inlet and outlet manifolds are configured to supply and exhaust coolant to the millichannels formed in the lower contact surface of another of the electronic device packages.

19. The stack of claim 12, wherein each of the upper contact surface and lower contact surface are circular in cross-section, and wherein each of the heat sinks is cylindrical in cross-section.

20. An integrated cooling stack comprising:
an upper heat sink defining a plurality of upper inlet manifolds for supplying a coolant and a plurality of upper outlet manifolds for exhausting the coolant;
a lower heat sink defining a plurality of lower inlet manifolds for supplying a coolant and a plurality of lower outlet manifolds for exhausting the coolant;
an upper thermal-expansion coefficient (CTE) matched plate defining a plurality of upper millichannels configured to receive the coolant from the upper inlet manifolds and to exhaust the coolant to the upper outlet manifolds; and
a lower CTE matched plate defining a plurality of lower millichannels configured to receive the coolant from the lower inlet manifolds and to exhaust the coolant to the lower outlet manifolds.

21. The integrated cooling stack of claim 20, further comprising an insulating housing, wherein the upper and lower heat sinks and the upper and lower CTE matched plates are disposed in the housing.

22. The integrated cooling stack of claim 20, wherein at least one of upper inlet and outlet manifolds and the lower inlet and outlet manifolds are disposed in a radial arrangement, and wherein at least one of the upper and lower millichannels are disposed in a circular arrangement.

23. The integrated cooling stack of claim 20, wherein at least one of the upper and lower millichannels are disposed in a radial arrangement, and wherein at least one of the upper and lower inlet and outlet manifolds are disposed in a circular arrangement.

24. The integrated cooling stack of claim 20, wherein each of the upper and lower (CTE) matched plates is circular in cross-section, and wherein each of the upper and lower heat sinks is circular in cross-section.

25. The integrated cooling stack of claim 20, further comprising:
a housing; and
at least one semiconductor device disposed on a wafer, wherein the wafer is disposed between the upper and lower CTE plates, and wherein each of the wafer, upper and lower CTE plates, and upper and lower heat sinks has a circular cross-section and is arranged in the housing to form a press-package.
